(19) United States
(12) Patent Application Publication
(10) Pub. No.: US 2015/0167171 A1
(43) Pub. Date: Jun. 18, 2015

(54) PROCESSING APPARATUS AND ACTIVE SPECIES GENERATING METHOD

(71) Applicant: TOKYO ELECTRON LIMITED, Tokyo (JP)

(72) Inventors: Kazuhide HASEBE, Nirasaki City (JP); Akira SHIMIZU, Nirasaki City (JP)

(21) Appl. No.: 14/573,765

(22) Filed: Dec. 17, 2014

(30) Foreign Application Priority Data
Dec. 18, 2013 (JP) 2013-261157

(51) Int. Cl. C23C 16/511; C23C 16/513

(52) U.S. Cl. CPC C23C 16/511; C23C 16/513

(57) ABSTRACT

A processing apparatus includes: a first active species generation unit including a first generation chamber where first active species are generated from a first gas by using silent discharge; a second active species generation unit including a second generation chamber where second active species are generated from a second gas by using at least one of inductively coupled plasma, capacitively coupled plasma and microwave plasma, the second active species generation unit being located downstream from the first active species generation unit and the first active species being supplied from the first generation chamber to the second generation chamber; and a processing chamber where a process is performed on an object to be processed by using the first and second active species supplied from the second generation chamber, the processing chamber being located downstream from the second active species generation unit.

### CROSS-REFERENCE TO RELATED APPLICATION

This application claims the benefit of Japanese Patent Application No. 2013-261157, filed on Dec. 18, 2013, in the Japan Patent Office, the disclosure of which is incorporated herein in its entirety by reference.

### TECHNICAL FIELD

The present disclosure relates to a processing apparatus and a method for generating active species.

### BACKGROUND

In a semiconductor integrated circuit device, a nitride film such as silicon nitride film (SiN), silicon oxynitride film (SiON), or the like is used as an insulating material. In the process of forming the nitride film, nitride active species such as N radicals or NH radicals are generated from a nitrogen-containing gas, and then the generated nitride active species are used as a nitriding agent. The nitride active species are generated from a nitrogen-containing gas through the use of various means such as capacitively coupled plasma, inductively coupled plasma or microwave plasma.

However, there is a problem in that the active species generated by means of the capacitively coupled plasma, inductively coupled plasma or microwave plasma have low concentration.

For example, the concentration of the active species is about 1×10¹⁰ cm⁻³ in the case of using the capacitively coupled plasma, and does not exceed 1×10¹² cm⁻³ even in the case of using the inductively coupled plasma or microwave plasma. When nitride active species (e.g., N radicals or NH radicals) and hydrogen radicals (e.g., H radicals) are generated from ammonia gas or a mixture gas of nitrogen gas and hydrogen gas, for example, the total amount of the generated active species meets the aforementioned concentrations.

On the other hand, a discharge method, for example, silent discharge, has been used to generate active species with high concentration. By using the silent discharge, the concentration of active species can be increased by about 100 times, i.e., to about 1×10¹⁴ cm⁻³, in comparison with the case using the inductively coupled plasma or microwave plasma.

However, although an active species with high concentration can be generated by using the silent discharge, there is a problem in that the silence discharge is usually performed at normal pressure and active species are easily inactivated at such a high pressure.

### SUMMARY

The present disclosure provides a processing apparatus, which is capable of generating active species with high concentration and supplying the active species into a processing chamber while suppressing inactivation of the active species, and an active species generating method.

According to an aspect of the present disclosure, a processing apparatus includes: a first active species generation unit that includes a first generation chamber where first active species are generated from a first gas containing active species sources by using silent discharge; a second active species generation unit that includes a second generation chamber where second active species are generated from a second gas containing active species sources by using at least one of inductively coupled plasma, capacitively coupled plasma and microwave plasma, the second active species generation unit being located downstream from the first active species generation unit and the first active species being supplied from the first generation chamber to the second generation chamber; and a processing chamber where a process is performed on an object to be processed by using the first and second active species supplied from the second generation chamber, the processing chamber being located downstream from the second active species generation unit.

According to another aspect of the present disclosure, an active species generating method includes: generating first active species from a first gas containing active species sources by using silent discharge; generating second active species from a second gas containing active species sources by using at least one of inductively coupled plasma, capacitively coupled plasma and microwave plasma; and supplying the first active species to a processing chamber where a process is performed on an object to be processed through a generation chamber where the second active species are generated.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross sectional view schematically illustrating a processing apparatus according to an embodiment of the present disclosure.

FIG. 2 is an enlarged cross sectional view of an active species generator.

FIG. 3A is a cross sectional view illustrating an example of a generation chamber of a second active species generation unit.

FIG. 3B is a cross sectional view illustrating a first modified example of the generation chamber of the second active species generation unit.

FIG. 3C is a cross sectional view illustrating a second modified example of the generation chamber of the second active species generation unit.

FIG. 3D is a cross sectional view illustrating a third modified example of the generation chamber of the second active species generation unit.

FIG. 4 is a cross sectional view schematically illustrating a first modified example of the processing apparatus.

FIG. 5 is a cross sectional view schematically illustrating a second modified example of the processing apparatus.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments. Throughout the drawings, the elements are denoted by the same reference numerals.

### Processing Apparatus

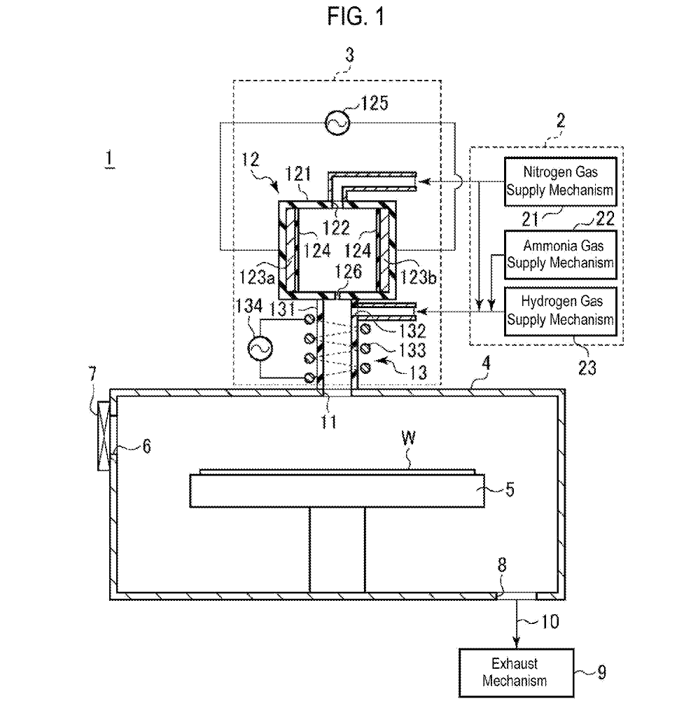

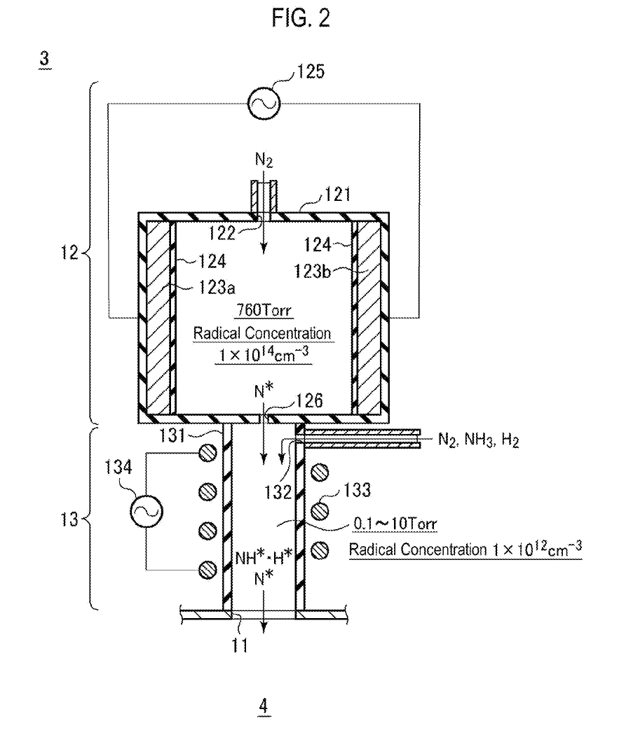

FIG. 1 is a cross sectional view schematically illustrating a processing apparatus according to an embodiment of the present disclosure. FIG. 2 is an enlarged cross sectional view of an active species generation unit of the processing apparatus.

As shown in FIGS. 1 and 2, a processing apparatus 1 according to an embodiment of the present disclosure includes a process gas supply source 2 for supplying gases containing active species sources and an active species generator 3 for generating active species from the gases containing active species sources supplied from the process gas supply source 2. The active species generated within the active species generator 3 is supplied to a processing chamber 4 where an object to be processed, e.g., a silicon wafer W, is accommodated and is subjected to a process using the active species.

A mounting table 5 is arranged within the processing chamber 4 and the silicon wafer W is mounted on the mounting table 5. A loading/unloading gate 6 for loading and unloading the silicon wafer W to and from the processing chamber 4 is formed in the side wall of the processing chamber 4. The loading/unloading gate 6 is opened and closed by a gate valve 7. An exhaust port 8 is formed in the bottom plate of the processing chamber 4 and is connected to an exhaust mechanism 9 through an exhaust pipe 10. The exhaust mechanism 9 performs air exhaust and pressure adjustment of the inside of the processing chamber 4. An active species supply hole 11 is formed in the ceiling plate of the processing chamber 4. The active species supply hole 11 is connected to the active species generator 3, and the active species generated in the active species generator 3 are supplied to the inside of the processing chamber 4 through the active species supply hole 11.

The process gas supply source 2 supplies process gases (gases containing active species sources in this embodiment) to the active species generator 3. By way of example, the processing apparatus 1 in this embodiment is a radical nitriding apparatus that performs radical nitriding of a thin film such as a silicon film, silicon oxide film or the like formed on the silicon wafer W. The process gas supply source 2 of this nitriding apparatus includes, for example, three gas supply mechanisms. The gas supply mechanisms may include a nitrogen gas supply mechanism 21, an ammonia gas supply mechanism 22 and a hydrogen gas supply mechanism 23.

The active species generator 3 in this example includes two active species generation units, i.e., a first active species generation unit 12 and a second active species generation unit 13. The first active species generation unit 12 generates first active species from a first gas containing active species sources by means of silent discharge, and the second active species generation unit 13 generates second active species from a second gas containing active species sources by using at least one of inductively coupled plasma, capacitively coupled plasma and microwave plasma. In this example, the second active species generation unit 13 generates the second active species by using inductively coupled plasma.

The first active species generation unit 12 includes a first generation chamber 121 where the first active species are generated. An active species source supply hole 122 for supplying the first gas containing active species sources is formed in the ceiling plate of the first generation chamber 121. The process gas supply source 2 supplies nitrogen gas (see “N₂” in FIG. 2) as the first gas to the inside of the first generation chamber 121 through the active species source supply hole 122.

The internal pressure of the first generation chamber 121 is set to, for example, normal pressure. The normal pressure is, for example, atmospheric pressure of about 1013 hPa (see “760 Torr” in FIG. 2). In the present disclosure, 1 Torr is defined as 133.3 Pa. In the first generation chamber 121 having the internal pressure of normal pressure, nitrogen radicals (see “N*” in FIG. 2) as the first active species are generated from the nitrogen gas (N₂) by means of silent discharge.

A pair of high-frequency electrodes 123a and 123b is installed inside of the first generation chamber 121. The high-frequency electrodes 123a and 123b are arranged within the first generation chamber 121 to face each other. A surface of each of the high-frequency electrodes 123a and 123b is covered by, for example, an insulation film 124. The high-frequency electrodes 123a and 123b are connected to a first high-frequency power supply 125. When a high-frequency electric power generated from the first high-frequency power supply 125 is applied to the high-frequency electrodes 123a and 123b, electrical discharge occurs inside of the first generation chamber 121, which causes the nitrogen gas (N₂) supplied into the first generation chamber 121 to produce the nitrogen radicals (N*). The nitrogen radicals (N*) are produced by a silent discharge, and thus the concentration of the nitrogen radicals (N*) (radical concentration) has an order of 1×10¹⁴ cm⁻³.

A discharge hole 126 for discharging the first active species is formed in a bottom plate of the first generation chamber 121. The nitrogen radicals (N*) having the concentration of 1×10¹⁴ cm⁻³ order are discharged through the discharge hole 126, and then are supplied to the inside of a second generation chamber 131 of the second active species generation unit 13.

The second active species generation unit 13 is installed downstream from the first active species generation unit 12. The second active species generation unit 13 includes the cylindrical-shaped second generation chamber 131 where the second active species are generated. A ceiling plate of the second generation chamber 131 serves as, for example, the bottom plate of the first generation chamber 121, and the discharge hole 126 is formed in the ceiling plate of the second generation chamber 131. The first active species having a concentration of 1×10¹⁴ cm⁻³ order (the nitrogen radicals (N*) in this example) are supplied from the first generation chamber 121 to the second generation chamber 131 through the discharge hole 126. An active species source supply hole 132 for supplying the second gas containing active species sources is formed in a side surface of the second generation chamber 131. Ammonia gas (see “NH₃” in FIG. 2), Nitrogen gas (see “N₂” in FIG. 2) and hydrogen gas (see “H₂” in FIG. 2) as the second gas are supplied from the process gas supply source 2 to the inside of the second generation chamber 131 through the active species source supply hole 132.

The internal pressure of the second generation chamber 131 is set to be lower than the internal pressure of the first generation chamber 121. In this example, the internal pressure of the second generation chamber 131 is set to be in a range from about 13.33 Pa to about 1333 Pa (see “0.1˜10 Torr” in FIG. 2). Due to the pressure difference between the first generation chamber 121 and the second generation chamber 131, the first active species (nitrogen radical (N*) in this example) are discharged from the first generation chamber 121 and introduced into the second generation chamber 131 through the discharge hole 126. A diameter of the cylindrical-shaped second generation chamber 131 is sufficiently larger than that of the discharge hole 126. Therefore, the nitrogen radicals (N*) having the concentration of 1×10¹⁴ cm⁻³ order are rapidly introduced into the second generation chamber 131 having an internal pressure from about 13.33 Pa to about 1333 Pa. In this manner, the nitrogen radicals (N*) are supplied to the inside of the second generation chamber 131. At the same time, in the second generation chamber 131, nitrogen radicals (see “N*” in FIG. 2), ammonia radicals (see “NH*” in FIG. 2) and hydrogen radials (see “H*” in FIG. 2) are generated from the nitrogen gas (N₂), ammonia gas (NH₃) and hydrogen gas (H₂) as the second active species by means of inductively coupled plasma.

Outside of the second generation chamber 131, a high-frequency coil 133 is installed. The high-frequency coil 133, for example, spirally surrounds the cylindrical-shaped second generation chamber 131. The high-frequency coil 133 is connected to a second high-frequency power supply 134. When a high-frequency electric power generated from the second high-frequency power supply 134 is applied to the high-frequency coil 133, an induced electric field is generated inside of the second generation chamber 131, which causes the nitrogen gas (N₂), ammonia gas (NH₃) and hydrogen gas (H₂) supplied into the second generation chamber 131 to produce the nitrogen radicals (N*), ammonia radicals (NH*) and hydrogen radials (H*). Since the inductively coupled plasma is used for generating those radicals, those radicals have a total concentration of, for example, an order of 1×10¹² cm⁻³.

The hydrogen gas (H₂) in the second gas is an additive for controlling film quality of a nitride film to be formed. Hydrogen introduced into the nitride film for controlling film quality may be obtained from the ammonia radicals (NH*) or hydrogen radicals (H*), both of which are generated from the ammonia gas (NH₃). If insufficient amount of hydrogen to be introduced is obtained from the ammonia gas (NH₃) only, the hydrogen gas (H₂) may be supplied, as in this example, to generate the hydrogen radicals (H*) also from the supplied hydrogen gas (H₂).

The processing chamber 4 is installed downstream of the second generation chamber 131. The bottom portion of the second generation chamber 131 is connected to the active species supply hole 11 formed in the ceiling plate of the processing chamber 4. The nitrogen radicals (N*), which are produced in the first generation chamber 121 and have the concentration of 1×10¹⁴ cm⁻³ order, is mixed with the nitrogen radicals (N*), ammonia radicals (NH*) and hydrogen radicals (H*), which are produced in the second generation chamber 131 and have the total concentration of 1×10¹² cm⁻³ order. Then, the mixture of those radicals is supplied into the processing chamber 4 through the active species supply hole 11. Therefore, in the processing chamber 4, a nitriding process using an atmosphere containing the nitrogen radicals (N*) having a concentration at least higher than 1×10¹4 cm⁻³ order may be performed on an object surface of the silicon wafer W.

According to the processing apparatus 2 of this embodiment, the nitrogen radicals (N*) having a high concentration of, for example, 1×10¹⁴ cm⁻³ order are generated in the first generation chamber 121, and then supplied into the processing chamber 4 via the second generation chamber 131. The second generation chamber 131 is, for example, in a state where inductively coupled plasma is formed therein and energy is applied thereto. Accordingly, it is difficult for the high-concentration nitrogen radicals (N*) supplied into the second generation chamber 131 to be inactivated in the second generation chamber 131. Therefore, the nitrogen radicals (N*) having a high concentration of 1×10¹⁴ cm⁻³ order can be supplied into the processing chamber 4.

Also, in the second generation chamber 131, the nitrogen radicals (N*), ammonia radicals (NH*) and hydrogen radicals (H*) having a low concentration of 1×10¹² cm⁻³ order are generated and mixed with the aforementioned nitrogen radicals (N*) having a high concentration of 1×10¹⁴ cm⁻³ order. This may increase the concentration of nitrogen radicals (N*), although the increment is a small amount of several percent.

A small amount of additive may be added in some cases, for example, in order to control film quality of the nitride film. In those cases, additive-containing radicals may be generated in the second generation chamber 131. In the aforementioned example, the additive-containing radicals are hydrogen-containing radicals such as the ammonia radicals (NH*) and hydrogen radicals (H*). In particular, it is advantageous to generate the additive-containing radicals in the second generation chamber 131 when excessive amounts of the additive-containing radicals, such as 1×10¹⁴ cm⁻³ order, exist. The reason is because, in the second generation chamber 131, the additive-containing radicals can be generated by an order of 1×10¹² cm⁻³, i.e., one-hundredth in amount in comparison with the case using the first generation chamber 121.

As described above, according to the processing apparatus 1 of this embodiment, it is possible to produce active species with high concentration and to supply the produced active species into a processing chamber while suppressing the active species from being in activated.

### Modified Examples of Second Generation Chamber 131

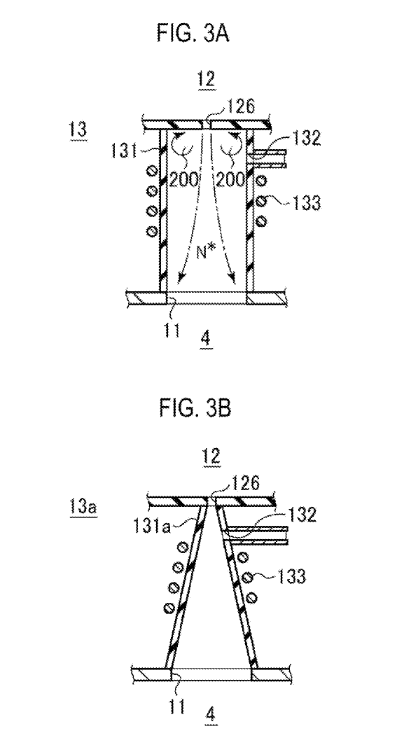

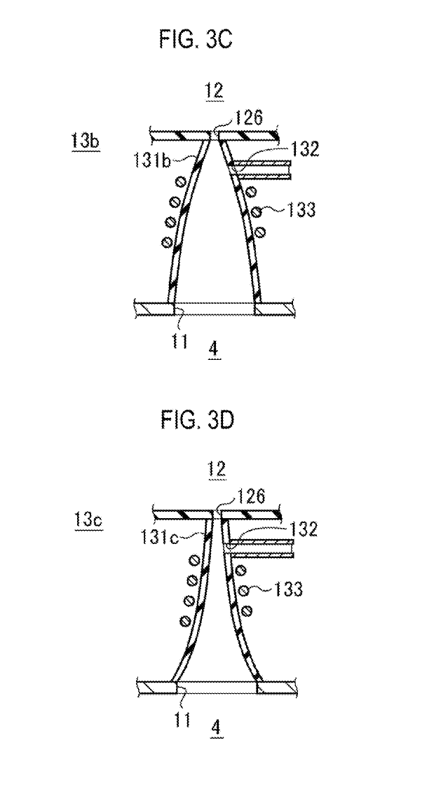

FIG. 3A is a cross sectional view illustrating an example of the second generation chamber 131 of the second active species generation unit 13 shown in FIGS. 1 and 2.

As shown in FIG. 3A, in the second active species generation unit 13 shown in FIGS. 1 and 2, the second generation chamber 131 has a cylindrical shape. The cylindrical shape is a basic shape of the second generation chamber 131. However, if the diameter of the cylindrical-shaped second generation chamber 131 is much larger than that of the discharge hole 126, turbulent flow 200 may be generated at a corner portion in the second generation chamber 131. When the turbulent flow 200 is generated, the nitrogen radicals (N*) are likely to be sucked into the turbulent flow 200 and brought into contact with the inner wall surface of the second generation chamber 131 which may cause the nitrogen radicals (N*) to be inactivated.

In order to suppress the inactivation of the nitrogen radicals (N*) due to the generation of the turbulent flow 200, the second generation chamber 131 may have a cylindrical shape wherein the diameter is small at the side of the first generation chamber 121 and large at the side of the processing chamber 4. Representative modified examples will be described below.

### First Modified Example

FIG. 3B is a cross sectional view illustrating a first modified example of the second generation chamber of the second active species generation unit.

As shown in FIG. 3B, in the first modified example, a second generation chamber 131a of a second active species generation unit 13a has a conical shape. In the conical shape, the side surface of the second generation chamber 131 a is formed along a straight line extending from the discharge hole 126 to the active species supply hole 11.

By forming the side surface of the second generation chamber 131a along the straight line extending from the discharge hole 126 to the active species supply hole 11, the portion where the turbulent flow 200 is generated may be eliminated, when compared to the second generation chamber 131 in FIG. 3A.

The second generation chamber 131a is advantageous in that the generation of the turbulent flow 200 can be suppressed, and in that the inactivation of the nitrogen radicals (N*) due to the phenomenon that the nitrogen radicals (N*) are sucked into the turbulent flow 200 can be suppressed.

### Second Modified Example

FIG. 3C is a cross sectional view illustrating a second modified example of the second generation chamber of the second active species generation unit.

As shown in FIG. 3C, in the second modified example, a second generation chamber 131b of a second active species generation unit 13b has a bell shape. In the bell shape, the side surface of the second generation chamber 131b is formed along a convex curve extending from the discharge hole 126 to the active species supply hole 11.

Similarly to the first modified example, in the second generation chamber 131b having the bell shape, the portion where the turbulent flow 200 is generated may be also eliminated, when compared to the second generation chamber 131 in FIG. 3A.

Accordingly, the second generation chamber 131b is also advantageous in that the generation of turbulent flow 200 can be suppressed, and in that the inactivation of the nitrogen radicals (N*) due to the phenomenon that the nitrogen radicals (N*) is sucked into the turbulent flow 200 can be suppressed.

### Third Modified Example

FIG. 3D is a cross sectional view illustrating a third modified example of the second generation chamber of the second active species generation unit.

As shown in FIG. 3D, in the third modified example, the second generation chamber 131c of the second active species generation unit 13c has a horn shape. Contrary to the bell shape, in the horn shape, the side surface of the second generation chamber 131c is formed along a concave curve extending from the discharge hole 126 to the active species supply hole 11.

Similarly to the first modified example, in the second generation chamber 131c having the horn shape, the portion where the turbulent flow 200 is generated may be also eliminated, when compared to the second generation chamber 131 in FIG. 3A.

Accordingly, the second generation chamber 131c is also advantageous in that the generation of turbulent flow 200 can be suppressed, and in that the inactivation of the nitrogen radicals (N*) due to the phenomenon that the nitrogen radicals (N*) is sucked into the turbulent flow 200 can be suppressed.

### Modified Examples of Processing Apparatus

### First Modified Example: Application to Film Forming Apparatus

The processing apparatus shown in FIGS. 1 and 2 is, for example, a nitriding apparatus. However, the processing apparatus according to this embodiment of the present disclosure may be not only applied to a surface processing/modification apparatus such as a nitriding apparatus, but also applied to a film forming apparatus.

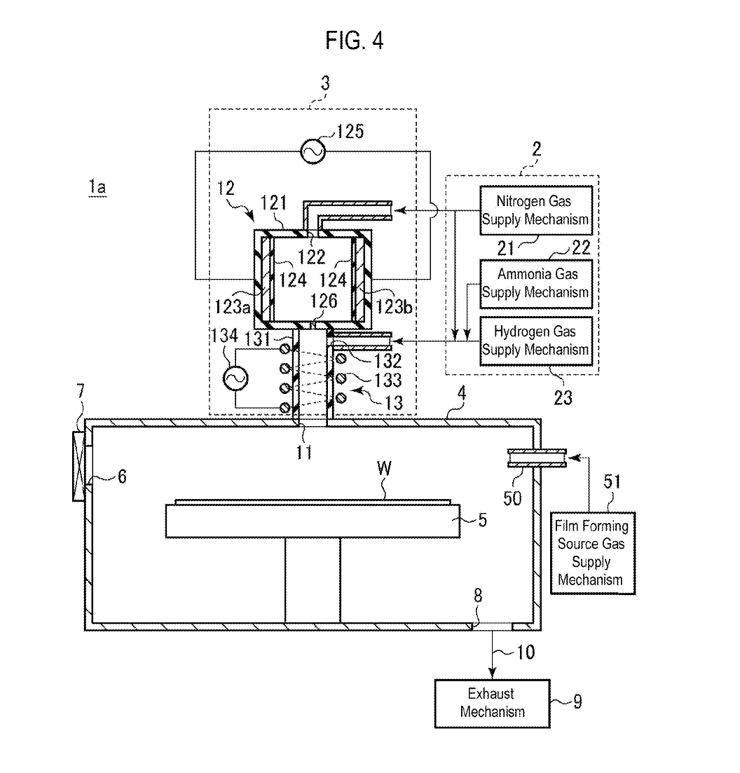

FIG. 4 is a cross sectional view schematically illustrating a first modified example of the processing apparatus.

As shown in FIG. 4, a processing apparatus 1a of the first modified example is different from the processing apparatus 1 shown in FIG. 1 in that a film forming source gas supply nozzle 50 for supplying a film forming source gas is installed in the processing chamber 4. The film forming source gas supply nozzle 50 is connected to a film forming source gas supply mechanism 51. The film forming source gas supply mechanism 51 supplies the film forming source gas into the processing chamber 4 through the film forming source gas supply nozzle 50. Therefore, the film forming source gas is supplied to the inside of the processing chamber 4, in addition to the nitrogen radicals (N*) and the like having a concentration of 1×10¹⁴ cm⁻³ order or higher.

By supplying the nitrogen radicals (N*) and the like having a concentration of 1×10¹⁴ cm⁻³ order or higher while supplying the film forming source gas into the processing chamber 4, a nitride film can be formed on an object surface of the silicon wafer W.

Alternatively, the nitride film can be formed on the object surface of the silicon wafer W by repeating: a sequence of forming a thin film on the object surface of the silicon wafer W by supplying the film forming source gas into the processing chamber 4 and a sequence of nitriding the thin film by supplying the nitrogen radicals (N*) and the like having the concentration of 1×10¹⁴ cm⁻³ order or higher to the formed thin film.

For example, monosilane (SiH₄) may be used as the film forming source gas. By using monosilane gas as the film forming source gas and using nitrogen radicals (N*), ammonia radicals (NH*) and hydrogen radicals (H*) as the active species, a silicon nitride film can be formed on the object surface of the silicon wafer W. The silicon nitride film formed by the aforementioned manner can be nitrided under an atmosphere where the total amount of nitrogen radicals (N*), ammonia radicals (NH*) and hydrogen radicals (H*) meets the concentration of 1×10¹⁴ cm⁻³ order or higher. Therefore, a silicon nitride film having good film quality can be formed even on a fine pattern.

As described above, the processing apparatus according to this embodiment of the present disclosure may be not only applied to a surface processing/modification apparatus such as a nitriding apparatus, but also applied to a film forming apparatus.

### Second Modified Example: Modification of Active Species Generator 3

The processing apparatus shown in FIGS. 1 and 2 includes only one active species generator 3. However, the processing apparatus according to this embodiment of the present disclosure is not limited to a single active species generator 3, and may include a plurality of active species generators 3.

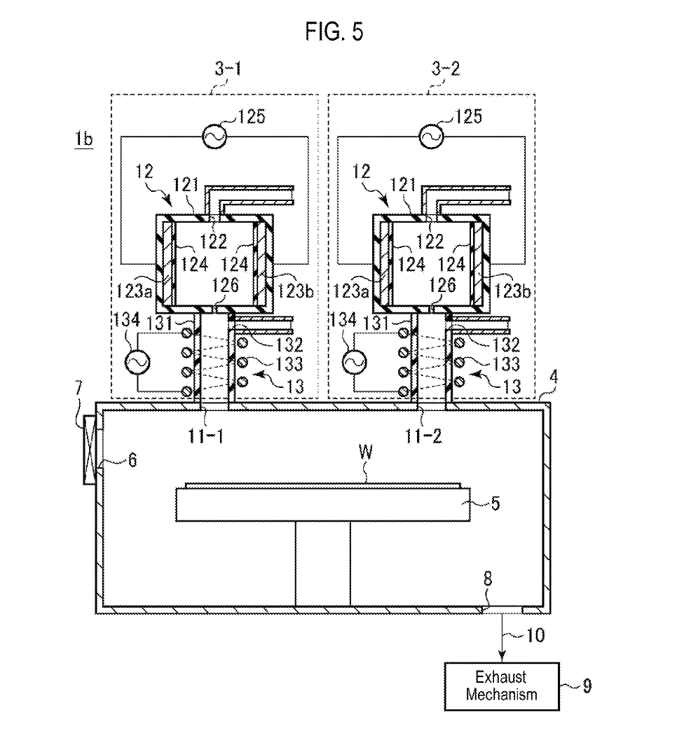

FIG. 5 is a cross sectional view schematically illustrating a second modified example of the processing apparatus.

As shown in FIG. 5, a processing apparatus 1b of the second modified example is different from the processing apparatus 1 shown in FIG. 1 in that a plurality of active species generators, e.g., two active species generators 3-1 and 3-2, is installed in the processing chamber 4. In this way, a plurality of active species generators, e.g., two active species generators 3-1 and 3-2, may be installed in the processing chamber 4, and nitrogen radicals (N*) and the like having the concentration of 1×10¹⁴ cm⁻³ order or higher may be supplied to the processing chamber 4 through a plurality of active species supply holes, e.g., two active species supply holes 11-1 and 11-2.

Installation of the plurality of active species generator 3-1 and 3-2 is advantageous in that the nitrogen radicals (N*) and the like can be more uniformly distributed within the processing chamber 4. Accordingly, it is possible to obtain more uniform film quality of a film formed by a nitriding processor to obtain more uniform film quality and thickness of a film formed by a film forming process.

While the present disclosure has been described with the above embodiment, the present disclosure is not limited to the above embodiment. The present disclosure described herein may be modified in a variety of other forms within the scope of the disclosure.

For example, in the above-described embodiment, nitrogen radicals (N*) are presented as the first active species. However, the first active species are not limited to nitrogen radicals (N*), and for example, oxygen radicals (O*) or OH radicals (OH*) may be used as the first active species. In this case, H₂O gas or N₂O gas may be used as the active species source gas.

Although nitrogen radicals (N*), ammonia radicals (NH*) and hydrogen radicals (H*) are presented as the second active species in the above-described embodiment, the second active species are not limited to those three types of radicals. The second active species merely need to include at least one of those three types of radicals. Although nitrogen gas, hydrogen gas and a compound gas of nitrogen and hydrogen (e.g., ammonia gas) are used as the second active species source gas in the above-described embodiment, only a mixture gas of nitrogen gas and hydrogen gas or only a compound gas of nitrogen and hydrogen may be used as the second active species source gas.

Alternatively, oxygen radicals (O*) or OH radicals (OH*) may be used as the second active species. In this case, H₂O gas or N₂O gas may be used as the active species source gas.

In the above-described embodiment, the second active species generation unit 13 generates the second active species from a gas containing active species sources by means of inductively coupled plasma. However, means for generating the second active species are not limited to inductively coupled plasma, and capacitively coupled plasma or microwave plasma, for example, may be used for generating the second active species. In other words, the second active species may be generated by using at least one of inductively coupled plasma, capacitively coupled plasma and microwave plasma.

In the above-described embodiment, the conical shape, bell shape and horn shape are presented as examples of the shape of the second generation chamber 131 having a cylindrical shape in which the cylinder is thin at the side of the first generation chamber 121 and thick at the side of the processing chamber 4. However, the second generation chamber 131 may have a shape of any combination of at least two of the conical shape, bell shape and horn shape.

While the above-described embodiment shows an example of a single-type substrate processing apparatus, the embodiment may be applied to a batch-type substrate processing apparatus. For example, the present disclosure may be applied to a vertical batch-type film forming apparatus that performs processes on silicon wafers W stacked in a vertical direction.

According to the present disclosure, it is possible to provide a processing apparatus, which is capable of generating active species with high concentration and supplying the active species into a processing chamber while suppressing inactivation of the active species, and an active species generating method.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A processing apparatus, comprising:
a first active species generation unit that includes a first generation chamber where first active species are generated from a first gas containing active species sources by using silent discharge;
a second active species generation unit that includes a second generation chamber where second active species are generated from a second gas containing active species sources by using at least one of inductively coupled plasma, capacitively coupled plasma and microwave plasma, the second active species generation unit being located downstream from the first active species generation unit and the first active species being supplied from the first generation chamber to the second generation chamber; and
a processing chamber where a process is performed on an object to be processed by using the first and second active species supplied from the second generation chamber, the processing chamber being located downstream from the second active species generation unit.

2. The processing apparatus of claim 1, wherein an internal pressure of the second generation chamber is set to be lower than an internal pressure of the first generation chamber.

3. The processing apparatus of claim 2, wherein the internal pressure of the first generation chamber is normal pressure.

4. The processing apparatus of claim 2, wherein the internal pressure of the second generation chamber is set within a range from 13.33 Pa to 1333 Pa.

5. The processing apparatus of claim 2, wherein the first active species are supplied from the first generation chamber to the second generation chamber by using a pressure difference between the internal pressure of the first generation chamber and the internal pressure of the second generation chamber.

6. The processing apparatus of claim 1, wherein the second active species are generated from the second gas within the second generation chamber, while the first active species having a concentration of 1×10¹⁴ cm⁻³ order are supplied from the first generation chamber to the second generation chamber.

7. The processing apparatus of claim 1, wherein each of the first and second gases includes at least one nitrogen-containing gas as the active species sources.

8. The processing apparatus of claim 7, wherein the nitrogen-containing gas of the first gas is different from the nitrogen-containing gas of the second gas.

9. The processing apparatus of claim 8, wherein the nitrogen-containing gas of the first gas is nitrogen gas and the nitrogen-containing gas of the second gas is a mixture gas of nitrogen gas and hydrogen gas or a compound gas of nitrogen and hydrogen.

10. The processing apparatus of claim 9, wherein the second gas includes hydrogen gas.

11. The processing apparatus of claim 1, wherein the second generation chamber has a cylindrical shape.

12. The processing apparatus of claim 11, wherein a diameter of the cylindrical shape is small at a side of the first generation chamber and large at a side of the processing chamber.

13. The processing apparatus of claim 12, wherein the cylindrical shape, which is thin at the side of the first generation chamber and thick at the side of the processing chamber, includes at least one of conical, bell and horn shapes or a combination of at least two of the conical, bell and horn shapes.

14. An active species generating method, comprising:
generating first active species from a first gas containing active species sources by using silent discharge;
generating second active species from a second gas containing active species sources by using at least one of inductively coupled plasma, capacitively coupled plasma and microwave plasma; and
supplying the first active species to a processing chamber where a process is performed on an object to be processed through a generation chamber where the second active species are generated.

15. The active species generating method of claim 14, wherein an internal pressure of the generation chamber where the second active species are generated is set to be lower than an internal pressure of another generation chamber where the first active species are generated.

16. The active species generating method of claim 15, wherein the second active species are generated from the second gas within the generation chamber where the second active species are generated, while the first active species having a concentration of 1×10¹⁴ cm⁻³ order are supplied from the another generation chamber where the first active species are generated to the generation chamber where the second active species are generated.
